(19) United States
(12) Patent Application Publication
(10) Pub. No.: US 2025/0231399 A1
(43) Pub. Date: Jul. 17, 2025

(54) MIRROR, IN PARTICULAR FOR A MICROLITHOGRAPHIC PROJECTION EXPOSURE APPARATUS, AND METHOD OF PROCESSING A MIRROR

(71) Applicant: Carl Zeiss SMT GmbH, Oberkochen (DE)

(72) Inventors: Eric EVA, Aalen (DE); Matthias KAES, Aalen (DE)

(21) Appl. No.: 19/170,404

(22) Filed: Apr. 4, 2025

Related U.S. Application Data
(63) Continuation of application No. PCT/EP2023/075902, filed on Sep. 20, 2023.

(30) Foreign Application Priority Data
Oct. 5, 2022 (DE) 10 2022 210 518.4

(51) Int. Cl. G02B 26/08; G03F 7/00

(52) U.S. Cl. CPC G02B 26/0858; G03F 7/70316; G03F 7/70958

(57) ABSTRACT

A microlithographic projection exposure mirror has an optical effective surface (11, 21, 31), a mirror substrate (12, 22, 32), a reflection layer system (17, 27, 37) reflecting electromagnetic radiation incident on the optical effective surface, and at least one piezoelectric layer (14, 24, 34) arranged between the substrate and the reflection layer system. An electric field for producing a locally variable deformation is applied by a first electrode arrangement (15, 25, 35) situated on the side of the piezoelectric layer facing the reflection layer system, and by a second electrode arrangement (13, 23, 33) situated on the side of the piezoelectric layer facing the mirror substrate. A layer (16, 26b, 36b) of amorphous material which is compaction-sensitive on exposure to low-energy electron beam radiation and which is arranged on the side of the piezoelectric layer facing the reflection layer system has a thickness of at least 20 μm.

### CROSS REFERENCE TO RELATED APPLICATIONS

This is a Continuation of International Application PCT/EP2023/075902 which has an international filing date of Sep. 20, 2023, and the disclosure of which is incorporated in its entirety into the present Continuation by reference. This Continuation also claims foreign priority under 35 U.S.C. § 119(a)-(d) to and also incorporates by reference, in its entirety, German Patent Application DE 10 2022 210 518.4 filed on Oct. 5, 2022.

### FIELD OF THE INVENTION

The invention relates to a mirror, in particular for a microlithographic projection exposure apparatus, and to a method of processing a mirror.

### BACKGROUND

Microlithography is used for producing microstructured components, such as for example integrated circuits or LCDs. The microlithography process is carried out in what is referred to as a projection exposure apparatus, which comprises an illumination device and a projection lens. The image of a mask (=reticle) illuminated by the illumination device is projected here with the projection lens onto a substrate (e.g. a silicon wafer) coated with a light-sensitive layer (=photoresist) and disposed in the image plane of the projection lens, in order to transfer the mask structure to the light-sensitive coating of the substrate.

In projection lenses designed for the extreme ultraviolet (EUV) wavelength range, which is to say at wavelengths of for example approximately 13 nm or approximately 7 nm, mirrors are used as optical components for the imaging process owing to the lack of availability of suitable light-transmissive refractive materials.

In this case, it is also known to configure one or more mirrors in an EUV system as an adaptive mirror with an actuator layer composed of a piezoelectric material, wherein an electric field having a locally varying strength is generated across this piezoelectric layer by an electrical voltage being applied to electrodes arranged on both sides with respect to the piezoelectric layer. In the case of a local deformation of the piezoelectric layer, the reflection layer stack of the adaptive mirror also deforms, with the result that, for example, imaging aberrations (possibly also temporally variable imaging aberrations) can be at least partly compensated for by suitable driving of the electrodes.

FIG. 5 shows a feasible construction of a conventional adaptive mirror 50, in a merely schematic illustration. The mirror 50 comprises in particular a mirror substrate 52 and also a reflection layer stack 51 and has a piezoelectric layer 56, which is produced from lead zirconate titanate (Pb(Zr, Ti)O3, PZT) in the example. Electrode arrangements are respectively situated above and below the piezoelectric layer 56, via which electrode arrangements an electric field for producing a locally variable deformation is able to be applied to the mirror 50. Out of said electrode arrangements, the second electrode arrangement facing the substrate 52 is configured as a continuous, planar electrode 54 of constant thickness, whereas the first electrode arrangement has a plurality of electrodes 60, to each of which an electrical voltage relative to the electrode 54 can be applied via a lead 59. The electrodes 60 are embedded into a common smoothing layer 58, which is produced e.g. from quartz (SiO2) and serves for levelling the electrode arrangement formed from the electrodes 60. Furthermore, the mirror 50 has, between the mirror substrate 52 and the bottom electrode 54 facing the mirror substrate 52, an adhesion layer 53 (e.g. composed of titanium, Ti) and a buffer layer 55 (e.g. composed of LaNiO3), which is arranged between the electrode arrangement 54 facing the substrate 52 and the piezoelectric layer 56 and which further supports the growth of PZT in an optimum, crystalline structure and ensures consistent polarization properties of the piezoelectric layer over the service life. In accordance with FIG. 5, the mirror 50 furthermore has a mediator layer 57. Said mediator layer 57 is in direct electrical contact with the electrodes 60 (which are illustrated in plan view in FIG. 1 only for description purposes). This mediator layer 57 serves to “mediate” between the electrodes 60 in terms of potential, in that it has only low electrical conductivity (preferably less than 200 siemens/metre (S/m)), with the consequence that any potential difference existing between adjacent electrodes 60 is dropped substantially across the mediator layer 57.

During operation of the mirror 50 or of an optical system comprising the mirror 50, applying an electrical voltage to the electrodes 54 and 60, by way of the electric field that forms, results in a deflection of the piezoelectric layer 56. In this way, it is possible—for instance for the compensation of optical aberrations e.g. owing to thermal deformations in the case of EUV radiation incident on the optical effective surface 51—to achieve an actuation of the mirror 50.

A problem that occurs in practice is that the smoothing layer 58 that exists in the above-described structure, which is typically intended to enable smoothing surface processing as a polishing layer during the process for production of the mirror, has comparatively high sensitivity to compaction, which results in particular from the preparation-related relatively low density of this layer which is generally produced from amorphous material by vapour deposition. However, increasing the density of the smoothing layer 58 by heat treatment at a temperature of several hundreds of degrees Celsius is not an option since this would destroy the piezoelectric layer 56.

The compaction sensitivity mentioned is found in practice firstly to be problematic with regard to the lifetime of the layer stack (because of any used EUV light that is already incident on the optical effective surface in the operation of the mirror and is partly transmitted through the reflection layer system). An additional aggravating factor is that the amorphous smoothing layer is itself already in spatially inhomogeneous distribution or has a variable thickness, namely if, as described above, the adjoining electrode arrangement and/or the piezoelectric layer as well is structured.

The above-discussed problem of the compaction sensitivity of the smoothing layer 58 also has the consequence that a further concept known in principle which is intended to bring about deliberate deformation or smoothing of the mirror in question in a controlled manner by low-energy electron beam bombardment of a mirror and associated compaction of the mirror substrate cannot be applied directly to an adaptive mirror having the structure described above with reference to FIG. 5: This is because the abovementioned marked compaction sensitivity of the smoothing layer 58 in conjunction with the spatial inhomogeneity thereof would then have the result of occurrence, in addition to the intended compaction of the mirror substrate 52, of compaction of the smoothing layer 58 which is significantly more marked and additionally spatially inhomogeneous and hence controllable only with difficulty, with the result that the ultimately desired establishment of a particular surface profile or a continuous planar surface of the mirror 50 is achievable only with difficulty.

By way of prior art, reference is made merely by way of example to DE 10 2013 219 583 A1, DE 10 2015 213 273 A1 and DE 10 2016 203 591 A1.

### SUMMARY

Objects of the present invention include providing a mirror, in particular for a microlithographic projection exposure apparatus, and a method of processing a mirror, which, on the basis of the principle of the locally varying deformation of a piezoelectric layer, enable correction of aberrations in the optical system while at least partly avoiding the problems described above.

This object is achieved in accordance with the features of the independent claims.

In one aspect, a mirror according to the invention, in particular for a microlithographic projection exposure apparatus, has:
an optical effective surface;
a mirror substrate;
a reflection layer system for reflecting electromagnetic radiation incident on the optical effective surface;
at least one piezoelectric layer which is arranged between the mirror substrate and the reflection layer system and to which an electric field for producing a locally variable deformation can be applied by way of a first electrode arrangement situated on the side of the piezoelectric layer facing the reflection layer system, and by way of a second electrode arrangement situated on the side of the piezoelectric layer facing the mirror substrate; and
a layer of amorphous material which is compaction-sensitive on exposure to low-energy electron beam radiation and which is arranged on the side of the piezoelectric layer facing the reflection layer system and has a thickness of at least 20 μm.

First of all, the present invention is based on the concept of undertaking, in an adaptive mirror having a piezoelectric layer that can be subjected via electrode arrangements to an electric field for producing a locally variable deformation, an electron beam processing operation not on the mirror substrate but on a compaction-sensitive layer that has been produced from amorphous material and is arranged close to the surface on the side of the piezoelectric layer facing the reflection layer system. The outcome achieved in this way is that processing of such an adaptive mirror is enabled even in the already “coated” state. Such a processing operation may be desirable or required in practice, for example, when the wavefront effect of the adaptive mirror which is achievable by subjecting the piezoelectric layer to an electric field is found to be no longer sufficient. At the same time, according to the invention, penetration of compacting radiation into the layer structure below the compaction-sensitive layer and hence protection of the spatially inhomogeneous region of this layer structure in particular is avoided by measures described hereinafter that may include suitable matching of the energy of the electron beam radiation, suitable choice of thickness of the compaction-sensitive layer, and suitable design of any blocking layer used in addition.

In this respect, an interdependence exists between the aforementioned (protective) measures in that, for instance, on the one hand, according to the energy of the electron beam radiation (and hence according to the penetration depth thereof) and according to the presence of a blocking layer (or the specific configuration thereof with regard to material and thickness), the thickness of the compaction-sensitive layer chosen may be comparatively lower, but, on the other hand, according to the thickness of the compaction-sensitive layer and depending on the energy of the electron beam radiation, it may be possible to dispense with a blocking layer entirely.

Proceeding from the above-described basic concept, the invention includes, in a first approach, the configuration, in an adaptive mirror having a piezoelectric layer that can be subjected via electrode arrangements to an electric field for producing a locally variable deformation, of choosing the thickness of a compaction-sensitive layer produced from amorphous material in sufficiently large size (i.e. with a value of at least 20 μm), with the result that the problems described at the outset in the case of (desired or else undesired) penetration of compacting radiation into the layer structure can be avoided.

If the compaction-sensitive layer having a thickness of at least 20 μm in accordance with the invention is a polishing layer which is to enable smoothing surface processing with embedding of a spatially inhomogeneous region of the layer structure (especially electrode arrangement and/or piezoelectric layer), the inventive choice of a sufficient thickness can achieve the effect that, when the adaptive mirror is exposed to a low-energy electron beam, this electron beam does not penetrate as far as said spatially inhomogeneous region of the layer structure, with the result that the problem of controllability of the compacting action of the electron beam bombardment used for controlled structuring or smoothing of the surface profile that was discussed at the outset is eliminated.

In one embodiment, the compaction-sensitive layer has a thickness of at least 50 μm, especially of at least 100 μm.

In embodiments of the invention, as already mentioned, an additional blocking layer composed of a material of high density (e.g. tungsten, W) and having suitable shielding properties for protection of said spatially inhomogeneous region of the layer structure from compacting radiation (especially an electron beam used in a controlled manner for surface smoothing) may also be present in the mirror of the invention. In such a use scenario, the compaction-sensitive layer of sufficient thickness (in this case one on the side of the blocking layer facing the reflection layer system) serves to provide a layer which is structurable and smoothable in a controlled manner via electron beam bombardment and associated compaction; at the same time, by virtue of this blocking layer, the spatially inhomogeneous region mentioned in the layer structure is not reached by the electron beam radiation given suitable choice of electron energy, and hence the problem of difficult controllability of the effect of the electron beam bombardment as a result of the spatial inhomogeneity is avoided.

In one embodiment, the mirror thus has a first blocking layer having transmittance of less than 10−6 for low-energy electron beam radiation.

In one embodiment, this first blocking layer is arranged between the compaction-sensitive layer and the first electrode arrangement.

The above configuration of the mirror with a blocking layer arranged between the compaction-sensitive layer and the first electrode arrangement, depending on the specific use scenario, enables protection of the first electrode arrangement even in the case of a lower thickness of the compaction-sensitive layer. Thus, the configuration of the mirror with a blocking layer arranged between the compaction-sensitive layer and the first electrode arrangement is advantageous in particular even without the existence of a thickness of the compaction-sensitive layer of at least 20 μm. In this case, i.e. in combination with a blocking layer arranged between the compaction-sensitive layer and the first electrode arrangement, it is especially also possible to choose a thickness of the compaction-sensitive layer of at least 1 μm.

In a further aspect, the invention thus also relates to a mirror, in particular for a microlithographic projection exposure apparatus, having:
an optical effective surface;
a mirror substrate;
a reflection layer system for reflecting electromagnetic radiation incident on the optical effective surface;
at least one piezoelectric layer, which is arranged between the mirror substrate and the reflection layer system and to which an electric field for producing a locally variable deformation is able to be applied by way of a first electrode arrangement situated on the side of the piezoelectric layer facing the reflection layer system, and by way of a second electrode arrangement situated on the side of the piezoelectric layer facing the mirror substrate;
a layer of amorphous material which is compaction-sensitive on exposure to low-energy electron beam radiation and which is arranged on the side of the piezoelectric layer facing the reflection layer system; and
a first blocking layer which is arranged between the compaction-sensitive layer and the first electrode arrangement and has transmittance of less than 10−6 for low-energy electron beam radiation.

In one embodiment, this first blocking layer contains a material from the group comprising tungsten (W), molybdenum (Mo), nickel (Ni) and chromium (Cr). Further metals having a high atomic number and high density are also usable. As will be described in more detail hereinafter, the thickness of the first blocking layer is suitably chosen according to the material and thickness of the compaction-sensitive layer provided in accordance with the invention.

In a further embodiment, it is also possible to provide two blocking layers in the layer structure of the adaptive mirror according to the invention, one of which is arranged as described above between the compaction-sensitive layer according to the invention and the spatially inhomogeneous region (i.e. structured electrode arrangement and/or piezoelectric layer) and, as likewise described above, ensures protection of this spatially inhomogeneous region from compacting radiation. The second blocking layer may then be disposed between the compaction-sensitive layer and the reflection layer system and may serve to shield the compaction-sensitive layer from the electromagnetic radiation used (e.g. EUV radiation) that is incident in operation of the mirror, i.e. only to “allow through” the “electron beam bombardment” used for controlled structuring or compaction to the compaction-sensitive layer.

In one embodiment, the mirror thus also has a second blocking layer having lower transmittance at least by a factor of five for electromagnetic radiation having a working wavelength of less than 30 nm, especially less than 15 nm, than for low-energy electron beam radiation.

In one embodiment, this second blocking layer is arranged between the compaction-sensitive layer and the reflection layer system.

The outcome is that the configuration according to the invention provides an adaptive mirror which is firstly actuatable in a controlled manner in terms of its optical wavefront effect by supply of electrical voltage, and in which, secondly, controlled structuring is also enabled by use of compacting electron beam bombardment, with the result that the former actuation achieved via application of voltage can be used completely, for example, for correction of dynamic imaging errors.

In one embodiment, the compaction-sensitive layer is configured as a polishing layer that enables smoothing surface processing with embedding of the at least one spatially inhomogeneous region of the layer structure, especially of the first electrode arrangement and/or of the piezoelectric layer.

In one embodiment, the amorphous material includes quartz glass (SiO2) or amorphous silicon (a-Si).

The invention also further relates to a method of processing a mirror, wherein the mirror has
an optical effective surface;
a mirror substrate;
a reflection layer system for reflecting electromagnetic radiation that is incident on the optical effective surface; and
at least one piezoelectric layer, which is arranged between the mirror substrate and the reflection layer system and to which an electric field for producing a locally variable deformation is able to be applied by way of a first electrode arrangement situated on the side of the piezoelectric layer facing the reflection layer system, and by way of a second electrode arrangement situated on the side of the piezoelectric layer facing the mirror substrate;
wherein a compaction-sensitive layer of amorphous material which is arranged on the side of the piezoelectric layer facing the reflection layer system, in order to generate compaction in this layer, is exposed to electron beam radiation having an energy of less than 100 keV.

This mirror may especially have the features described above. In particular, this may be a mirror with or without an additional blocking layer, wherein the thickness of the compaction-sensitive layer subjected to electron beam radiation can also be chosen suitably (i.e., according to the presence of a blocking layer and depending on the energy of the electron beam radiation, possibly also at less than 20 μm, possibly also less than 5 μm).

In one embodiment, the mirror has, between the compaction-sensitive layer and the first electrode arrangement, a blocking layer having transmittance of less than 10−6 for the electron beam radiation.

In one embodiment, the energy from the electron beam radiation and the thickness of the compaction-sensitive layer are chosen such that the electron beam radiation does not penetrate into the mirror as far as the first electrode arrangement which is situated on the side of the piezoelectric layer facing the reflection layer system.

In one embodiment, the energy of the electron beam radiation is less than 100 keV, especially less than 60 keV, more particularly less than 30 keV, and more particularly less than 20 keV. Since the penetration depth of the electron beam radiation into the mirror also decreases when its energy is reduced, this reduction in energy of the electron beam radiation makes it feasible to dispense with a blocking layer and/or reduce the thickness of the compaction-sensitive layer exposed to the electron beam radiation.

In one embodiment, the energy of the electron beam radiation is varied during processing. In this way, it becomes possible, for example, to take account of a manufacturing-related variation in thickness of the compaction-sensitive layer or any variance from the nominal thickness in that the respective irradiation energy is adjusted individually in the processing with electron beam radiation.

The invention further relates to an optical system of a microlithographic projection exposure apparatus, in particular an illumination device or a projection lens, comprising at least one mirror having the above-described features, and also to a microlithographic projection exposure apparatus.

Further configurations of the invention are apparent from the description and the dependent claims.

The invention is explained in greater detail below on the basis of exemplary embodiments illustrated in the accompanying figures.

### BRIEF DESCRIPTION OF THE DRAWINGS

The figures show:

FIG. 1 a schematic illustration for explaining the construction of an adaptive mirror in accordance with one embodiment of the invention;

FIGS. 2-3 schematic illustrations for describing the construction of an adaptive mirror in accordance with further embodiments of the invention;

FIG. 4 a schematic illustration showing a representative construction of a microlithographic projection exposure apparatus designed for operation in the EUV; and

FIG. 5 a schematic illustration showing a representative construction of a conventional adaptive mirror.

### DETAILED DESCRIPTION

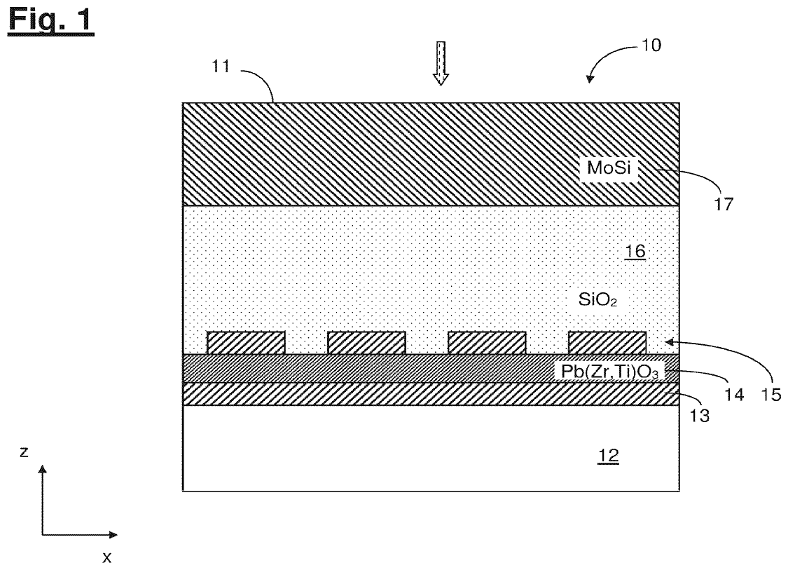

A common factor in the embodiments described hereinafter with reference to FIGS. 1-3 is that a respective compaction-sensitive layer of amorphous material is used in an adaptive mirror having a piezoelectric layer and electrode arrangements. This firstly enables structuring by electron beam bombardment and associated compaction, and secondly avoids any adverse effect of a spatially inhomogeneous region within the layer structure (typically because of spatial structuring of an electrode arrangement and/or the piezoelectric layer) on the controllability of the structuring or the thickness profile ultimately established.

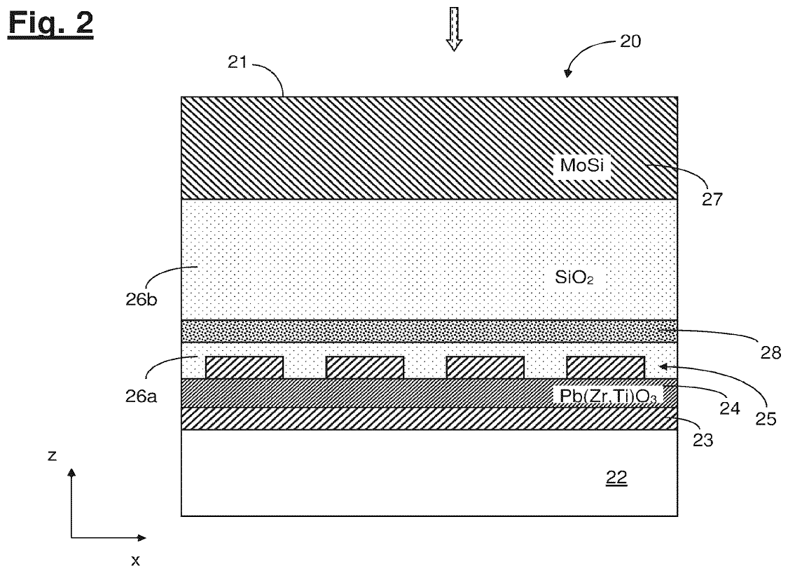

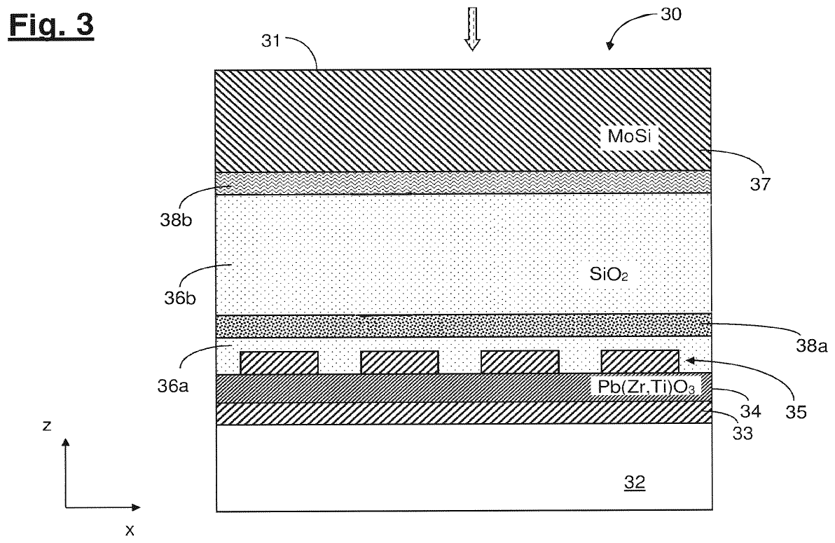

The difference in the embodiments described hereinafter is that, in FIG. 1, a protective effect is achieved with regard to the spatially inhomogeneous region from compacting radiation by virtue of the thickness of the compaction-sensitive layer itself, whereas, in FIG. 2 and FIG. 3, an additional blocking layer is achieved in each case for assuring this protective effect. In the presence of the additional blocking layer, it becomes possible to choose a lower thickness of the compaction-sensitive layer. Ultimately, it is rendered possible here, as described in detail hereinafter, to suitably choose the thickness of the compaction-sensitive layer depending on the material and the thickness of the blocking layer, and also on the energy of the electron beam radiation. In addition, a protective effect can also be achieved with regard to the spatially inhomogeneous region from compacting radiation in that the energy of the electron beam radiation chosen is low (e.g. less than 30 keV). In this case, even in the case of a comparatively low thickness of the compaction-sensitive layer, it becomes optionally possible to dispense with the blocking layer.

FIG. 1 shows a schematic illustration showing the construction of a mirror 10 according to the invention in one exemplary embodiment of the invention. The mirror 10 comprises in particular a mirror substrate 12, which is produced from any desired suitable mirror substrate material. Suitable mirror substrate materials are e.g. quartz glass doped with titanium dioxide (TiO2), with materials that are usable being, merely by way of example (and without the invention being restricted thereto), those sold under the trade names ULE® (from Corning Inc.) or Zerodur® (from Schott AG).

Furthermore, the mirror 10 has, in a manner known per se in principle, a reflection layer system 17, which, in the embodiment illustrated, comprises merely by way of example a molybdenum-silicon (Mo—Si) layer stack. Without the invention being restricted to specific configurations of the reflection layer system, one merely illustrative suitable construction may comprise about 50 plies or layer assemblies of a layer system comprising molybdenum (Mo) layers each having a layer thickness of 2.4 nm and silicon (Si) layers each having a layer thickness of 3.3 nm.

The mirror 10 can be in particular an EUV mirror of an optical system, in particular of the projection lens or of the illumination device of a microlithographic projection exposure apparatus.

It should be pointed out that the mirror 10, merely for depicting the layer structure and for the purpose of simpler representation, is shown in planar form both in FIG. 1 and in the further embodiments, but may also have any other geometries (for example including convex or concave).

The incidence of electromagnetic EUV radiation on an optical effective surface 11 of the mirror 10 during operation of the optical system can result in an inhomogeneous change in volume of the mirror substrate 12 because of the temperature distribution which arises from the absorption of radiation incident inhomogeneously on the optical effective surface 11. For correction of such an unwanted change in volume or else for correction of other aberrations that occur in operation of the microlithographic projection exposure apparatus, the mirror 10 has an adaptive design, and for this purpose has a piezoelectric layer 14 which, in the exemplary embodiment, has been produced from lead zirconate titanate (Pb(Zr, Ti)O3, PZT). In further embodiments, the piezoelectric layer 14 can also be produced from some other suitable material (e.g. aluminium nitride (AlN), aluminium scandium nitride (AlScN), lead magnesium niobate (PbMgNb) or vanadium-doped zinc oxide (ZnO)).

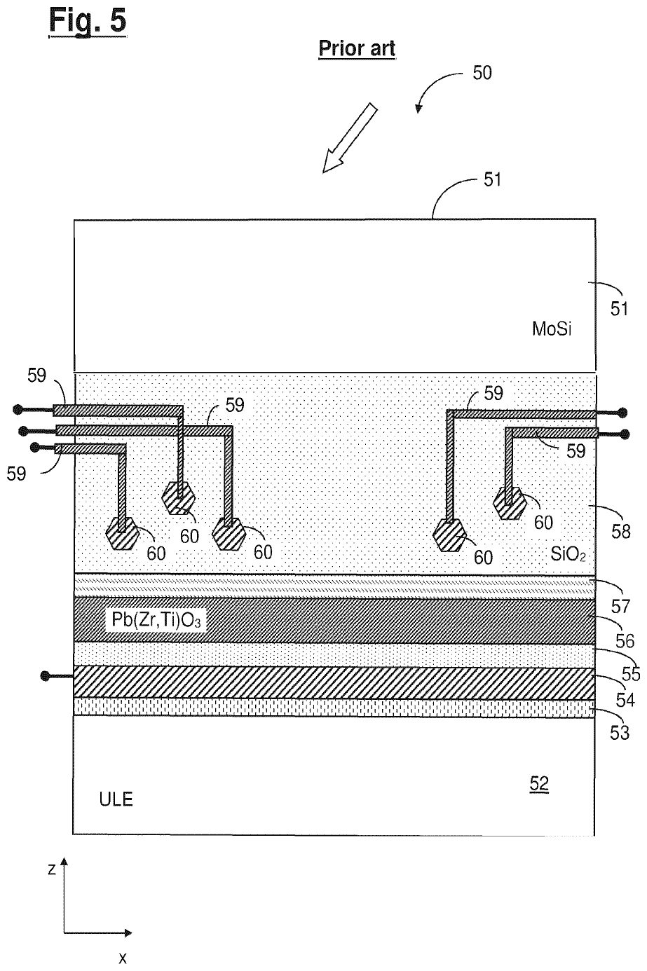

In addition, the mirror 10 may have further functional layers which are not shown for simplicity in FIG. 1, for example tie layer, buffer layer or mediator layer, analogously to the conventional structure already described with reference to FIG. 5.

The piezoelectric layer 14 can be exposed to an electric field for producing a locally variable deformation via a first electrode arrangement 15 which is situated on the side of the piezoelectric layer 14 facing the reflection layer system 17 and has a multitude of independently actuatable electrodes (connected to feeds that are not shown), and a second electrode arrangement 13 (in the form of a continuous electrode) which is situated on the side of the piezoelectric layer 14 facing the mirror substrate 12. The invention is generally not restricted to specific geometries of the electrodes or distances therebetween (wherein the distance between the electrodes can also be e.g. a number of millimetres (mm) or a number of centimetres (cm)).

During operation of the mirror 10 or of an optical system comprising such a mirror 10, in a manner known per se, applying an electrical voltage to the electrodes of the electrode arrangement 15, by way of the electric field that forms in the region of the piezoelectric layer 14, results in a deflection of the piezoelectric layer 14. In this way, it becomes possible to achieve an actuation of the mirror 10 for the compensation of optical aberrations.

The electrodes of the electrode arrangement 15 are each embedded into a smoothing layer which is produced from quartz (SiO2) in the exemplary embodiment and serves to level the electrode arrangement 15 formed from the electrodes. A compaction-sensitive layer 16 that serves as smoothing layer according to FIG. 1 has a thickness of at least 5 μm, especially at least 20 μm, more particularly at least 50 μm and more particularly at least 100 μm.

As apparent from FIG. 1, the multitude of independently actuatable electrodes in the electrode arrangement 15 produces a spatially inhomogeneous region, with the result that the compaction-sensitive layer 16 that serves as smoothing layer does not have a uniform thickness, but instead itself extends in a spatially inhomogeneous manner into interstices or “gaps” that remain between these electrodes.

Through electron beam bombardment (indicated by an arrow in FIG. 1) of the layer structure, it then becomes possible to achieve a controlled compacting effect within the compaction-sensitive layer 16. At the same time, the energy of the electron beam can be chosen such that this electron beam does not penetrate as far as the electrode arrangement 15 and the spatially inhomogeneous region formed thereby. Electron beam energies suitable for this purpose may be in the range from 5 keV to 100 keV. As a result, the problem of difficult controllability of the effect of electron beam bombardment as a result of the abovementioned spatial inhomogeneity is thus avoided.

It should be pointed out that the invention is not limited to the specific configuration of the adaptive mirror of FIG. 1 (or FIGS. 2-3). Thus, in further embodiments, a spatial inhomogeneity can in particular also result from formation of the piezoelectric layer 17 itself in a structured manner, or in a spatially inhomogeneous manner owing to the subdivision into multiple segments that are adjacent laterally (i.e. within the x-y plane).

FIG. 2 shows a further embodiment, wherein components that are analogous or substantially functionally identical in comparison with FIG. 1 are designated by reference numerals increased by “10”.

In FIG. 2, by contrast with the embodiment of FIG. 1, an additional blocking layer 28 composed of a material of high density (e.g. tungsten, W) and having suitable shielding properties is used for protecting the spatially inhomogeneous region of the layer structure from compacting radiation (especially an electron beam used in a controlled manner for surface smoothing).

The compaction-sensitive layer 26b is arranged here on the side of the blocking layer 28 facing the reflection layer system 27 and serves to provide a layer that is structurable in a controlled manner via the electron beam radiation and associated compaction. At the same time, the blocking layer 28 has the effect that the spatially inhomogeneous region mentioned in the layer structure is not reached by the electron beam radiation given suitable choice of electron energy, such that the problem described at the outset of difficult controllability of the effect of the electron beam bombardment is avoided as a result of the spatial inhomogeneity of the layer structure.

The thickness of the compaction-sensitive layer can be chosen depending on the material and the thickness of the blocking layer, and also on the energy of the electron beam radiation. Since, from a quantitative point of view, the structurability of the compaction-sensitive layer 26b stemming from compaction is in the order of magnitude of about 1%, it is possible by way of example to achieve structuring in the order of magnitude of about 1 μm with a thickness of the compaction-sensitive layer 26b of 100 μm.

Tables 1 to 4 below show illustrative embodiments with regard to suitable thicknesses of the compaction-sensitive layer according to the presence, material and thickness of any blocking layer present, and according to the energy of the electron beam radiation, the values having been calculated by Monte Carlo simulations.

TABLE 1
Necessary thickness of the blocking layer with electron beam
radiation energy of 60 keV depending on the blocking layer
material and thickness of the compaction-sensitive layer:

| | 5 μm | 10 μm | 15 μm | 20 μm |
|---|---|---|---|---|
| Tungsten | 1500 nm | 1200 nm | 1000 nm | 500 nm |
| (W) | | | | |
| Molybdenum | 4500 nm | 3000 nm | 2000 nm | 2000 nm |
| (Mo) | | | | |
| Nickel (Ni) | 5000 nm | 4000 nm | 3000 nm | 2500 nm |

TABLE 2
Necessary thickness of the blocking layer with electron beam
radiation energy of 50 keV depending on the blocking layer
material and thickness of the compaction-sensitive layer:

| | 5 μm | 10 μm | 15 μm | 20 μm |
|---|---|---|---|---|
| Tungsten | 1000 nm | 750 nm | 500 nm | 300 nm |
| (W) | | | | |
| Molybdenum | 2500 nm | 1500 nm | 1000 nm | 750 nm |
| (Mo) | | | | |
| Nickel (Ni) | 3500 nm | 2000 nm | 1500 nm | 1000 nm |

TABLE 3
Necessary thickness of the blocking layer with electron beam
radiation energy of 40 keV depending on the blocking layer
material and thickness of the compaction-sensitive layer:

| | 5 μm | 10 μm | 15 μm | 20 μm |
|---|---|---|---|---|
| Tungsten | 750 nm | 500 nm | — | — |
| (W) | | | | |
| Molybdenum | 1500 nm | 750 nm | — | — |
| (Mo) | | | | |
| Nickel (Ni) | 2000 nm | 1000 nm | — | — |

TABLE 4
Necessary thickness of the blocking layer with electron beam
radiation energy of 30 keV depending on the blocking layer
material and thickness of the compaction-sensitive layer:

| | 5 μm | 10 μm | 15 μm | 20 μm |
|---|---|---|---|---|
| Tungsten | 250 nm | — | — | — |
| (W) | | | | |
| Molybdenum | 500 nm | — | — | — |
| (Mo) | | | | |
| Nickel (Ni) | 400 nm | — | — | — |

In the case of an electron beam radiation energy of 20 keV or less, even for a thickness of the compaction-sensitive layer of 5 μm (or more), achievement of the desired protective effect of the layer structure beneath the compaction-sensitive layer does not require a blocking layer.

FIG. 3 shows a further embodiment, wherein, once again, components which are analogous or substantially have the same function are denoted by reference signs increased by “10” in relation to FIG. 2.

In the embodiment of FIG. 3, two blocking layers 38a, 38b are provided in the layer structure of an adaptive mirror 30, one of which, as described above, is arranged between the compaction-sensitive layer 38a according to the invention and a spatially inhomogeneous region formed by the structured electrode arrangement 35, and, as likewise described, ensures protection of this spatially inhomogeneous region from compacting radiation. The second blocking layer 38b is disposed between the compaction-sensitive layer 36b and the reflection layer system 37, and serves to shield the compaction-sensitive layer 36b from electromagnetic radiation used (e.g. EUV radiation) which is incident during operation of the mirror. As a result, only the “electron beam bombardment” used in a controlled manner for structuring or compaction is “allowed through” to the compaction-sensitive layer 36b. For this purpose, the second blocking layer 38b has lower transmittance at least by a factor of five for electromagnetic radiation having a working wavelength of less than 30 nm, especially less than 15 nm, than for low-energy electron beam radiation. Illustrative suitable thicknesses of the blocking layers 28, 38a and 38b, according to the material, may, for example, be in the range from 100 nm to 5000 nm.

The thickness of the compaction-sensitive layer 36b, analogously to FIG. 2, can be chosen depending on the material and the thickness of the blocking layers, and also on the energy of the electron beam radiation.

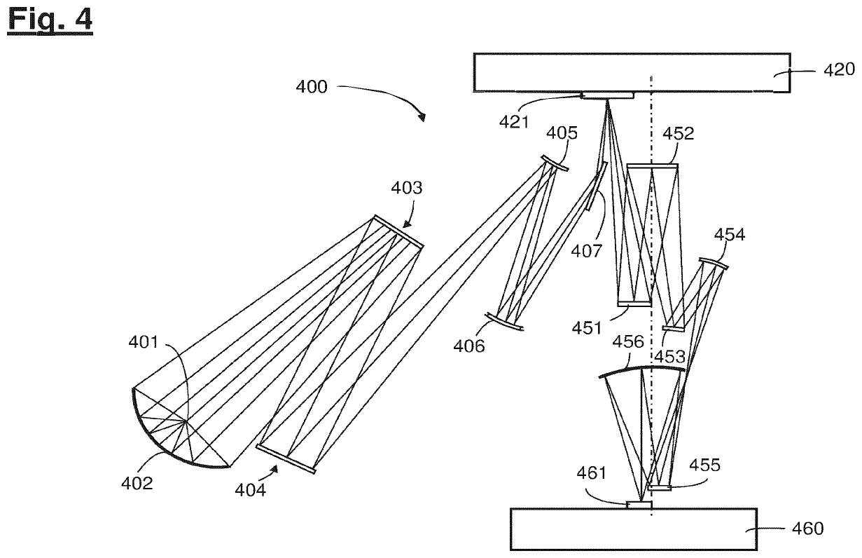

FIG. 4 shows a schematic illustration of a representative projection exposure apparatus which is designed for operation in the EUV wavelength rand and in which the present invention is implementable.

According to FIG. 4, an illumination device in a projection exposure apparatus 400 designed for EUV radiation comprises a field facet mirror 403 and a pupil facet mirror 404. The light from a light source unit comprising a plasma light source 401 and a collector mirror 402 is directed at the field facet mirror 403. A first telescope mirror 405 and a second telescope mirror 406 are arranged downstream of the pupil facet mirror 404 in the light path. Arranged downstream in the light path is a deflection mirror 407, which directs the radiation incident on it at an object field in the object plane of a projection lens comprising six mirrors 451-456. At the location of the object field, a reflective structure-bearing mask 421 is arranged on a mask stage 420 and with the aid of the projection lens is imaged into an image plane, in which a substrate 461 coated with a light-sensitive layer (photoresist) is situated on a wafer stage 460.

Merely by way of example, it is possible to configure any mirror 451-456 in the projection lens in the inventive manner.

Even though the invention has also been described on the basis of specific embodiments, numerous variations and alternative embodiments will be apparent to a person skilled in the art, for example by the combination and/or exchange of features of individual embodiments. Accordingly, such variations and alternative embodiments are concomitantly encompassed by the present invention, and the scope of the invention is restricted only within the meaning of the appended claims and the equivalents thereof.

What is claimed is:

1. Mirror having an optical effective surface, comprising:
a mirror substrate;
a reflection layer system that reflects electromagnetic radiation incident on the optical effective surface;
at least one piezoelectric layer arranged between the mirror substrate and the reflection layer system; and
a first electrode arrangement situated on a side of the piezoelectric layer facing the reflection layer system and a second electrode arrangement situated on a side of the piezoelectric layer facing the mirror substrate; and
a layer of amorphous material which is compaction-sensitive on exposure to low-energy electron beam radiation, which is arranged on the side of the piezoelectric layer facing the reflection layer system, and which has a thickness of at least 50 μm;
wherein the first electrode arrangement and the second electrode arrangement are arranged to produce a locally variable deformation in the piezoelectric layer in response to application of an electric field.

2. Mirror according to claim 1 and configured for a microlithographic projection exposure apparatus.

3. Mirror according to claim 1, wherein the layer of amorphous material has a thickness of at least 100 μm.

4. Mirror according to claim 1, wherein:
at least one of the piezoelectric layer, the first electrode arrangement and the second electrode arrangement comprise at least one spatially inhomogeneous region, and
the compaction-sensitive layer is configured as a polishing layer enabling smooth surface processing by embedding the at least one spatially inhomogeneous region.

5. Mirror according to claim 1, further comprising a first blocking layer which has transmittance of less than 10⁻⁶ for low-energy electron beam radiation.

6. Mirror according to claim 5, wherein the first blocking layer is arranged between the compaction-sensitive layer and the first electrode arrangement.

7. Mirror having an optical effective surface, comprising:
a mirror substrate;
a reflection layer system that reflects electromagnetic radiation incident on the optical effective surface;
at least one piezoelectric layer arranged between the mirror substrate and the reflection layer system;
a first electrode arrangement situated on a side of the piezoelectric layer facing the reflection layer system and a second electrode arrangement situated on a side of the piezoelectric layer facing the mirror substrate;
a layer of amorphous material which is compaction-sensitive on exposure to low-energy electron beam radiation and which is arranged on the side of the piezoelectric layer facing the reflection layer system; and
a first blocking layer arranged between the compaction-sensitive layer and the first electrode arrangement, and having a transmittance of less than 10⁻⁶ for low-energy electron beam radiation;
wherein the first electrode arrangement and the second electrode arrangement are arranged to produce a locally variable deformation in the piezoelectric layer in response to application of an electric field, and
wherein the first blocking layer contains a material selected from the group consisting essentially of tungsten (W), molybdenum (Mo), nickel (Ni) and chromium (Cr).

8. Mirror according to claim 7 and configured for a microlithographic projection exposure apparatus.

9. Mirror according to claim 7, further comprising a second blocking layer which has a transmittance lower by at least a factor of five for electromagnetic radiation having a working wavelength of less than 30 nm than for the low-energy electron beam radiation.

10. Mirror according to claim 9, wherein the second blocking layer is arranged between the compaction-sensitive layer and the reflection layer system.

11. Mirror according to claim 7, wherein the amorphous material includes quartz glass (SiO₂) or amorphous silicon (a-Si).

12. Mirror according to claim 7 and configured for an operating wavelength of less than 30 nm.

13. Mirror according to claim 7 and configured for an operating wavelength of less than 15 nm.

14. Method for processing a mirror having:
an optical effective surface;
a mirror substrate;
a reflection layer system configured to reflect electromagnetic radiation incident on the optical effective surface;
said method comprising:
arranging at least one piezoelectric layer between the mirror substrate and the reflection layer system;
applying an electric field for producing a locally variable deformation by situating a first electrode arrangement on a side of the piezoelectric layer facing the reflection layer system and by situating a second electrode arrangement on a side of the piezoelectric layer facing the mirror substrate; and
arranging a compaction-sensitive layer of amorphous material on the side of the piezoelectric layer facing the reflection layer system and generating compaction in the compaction-sensitive layer; and
exposing the compaction-sensitive layer to electron beam radiation having an energy of less than 100 keV.

15. Method according to claim 14, wherein the mirror further has, between the compaction-sensitive layer and the first electrode arrangement, a blocking layer that has a transmittance of less than 10⁻⁶ for the electron beam radiation.

16. Method according to claim 14, further comprising selecting the energy from the electron beam radiation and the thickness of the compaction-sensitive layer such that the electron beam radiation does not penetrate into the mirror as far as the first electrode arrangement situated on the side of the piezoelectric layer facing the reflection layer system.

17. Method according to claim 14, wherein the energy of the electron beam radiation is less than 100 keV.

18. Method according to claim 14, further comprising varying the energy of the electron beam radiation during said exposing.

19. Optical system comprising an illumination device or a projection lens of a microlithographic projection exposure apparatus, and a mirror according to claim 1.

20. Microlithographic projection exposure apparatus comprising an illumination device and a projection lens, and a mirror according to claim 7.
